(19) United States
(12) Patent Application Publication
(10) Pub. No.: US 2016/0066418 A1
(43) Pub. Date: Mar. 3, 2016

(54) PART-EMBEDDED CIRCUIT STRUCTURE AND METHOD FOR MANUFACTURING SAME

(71) Applicants: HongQiSheng Precision Electronics (QinHuangDao) Co.,Ltd., Qinhuangdao (CN); FuKui Precision Component (Shenzhen) Co., Ltd., Shenzhen (CN); Zhen Ding Technology Co., Ltd., Tayuan (TW)

(72) Inventors: YU-HAO CHENG, New Taipei (TW); YUE WANG, Qinhuangdao (CN); WEN-HUNG HU, New Taipei (TW)

(21) Appl. No.: 14/841,720

(22) Filed: Sep. 1, 2015

(30) Foreign Application Priority Data
Sep. 2, 2014 (CN) 201410442073.6

(51) Int. Cl. H05K 1/02; H05K 3/46; H05K 3/42; H05K 1/11

(52) U.S. Cl. CPC H05K 1/0298; H05K 1/111; H05K 1/115; H05K 3/4652; H05K 3/421; H05K 3/4661; H05K 3/4682; H05K 2201/09509

(57) ABSTRACT

A method for manufacturing a part-embedded circuit structure includes: forming an inner resist layer with an opening on a base member to expose a portion of the base member; forming an inner wiring layer on the inner resist layer which extends into the opening of the inner resist layer; laminating a dielectric layer on the inner wiring layer; forming an outer wiring layer on the dielectric layer opposite to the inner wiring layer; and removing the base member to expose the inner wiring layer in the opening and the inner resist layer such that a level plane is formed.

### FIELD

The subject matter herein generally relates to a part-embedded circuit structure and a method for manufacturing the part-embedded circuit structure.

### BACKGROUND

An embedded circuit structure usually includes a dielectric material, inner wiring layers, an outer wiring layer, and two resist layers. The dielectric material includes two opposite surfaces. The inner wiring layers are embedded in the dielectric material and exposed from one surface of the dielectric material. The outer wiring layer is formed on the other surface of the dielectric layer. One of the two resist layers covers the inner wiring layer. The other of the two resist layers covers the outer wiring layer. The resist layer covering the inner wiring layer defines a plurality of openings. A portion of the inner wiring layer is exposed from the openings.

### BRIEF DESCRIPTION OF THE DRAWINGS

Implementations of the present technology will now be described, by way of example only, with reference to the attached figures.

FIG. 1 is a flow chart of an example embodiment of a method for manufacturing a part-embedded circuit structure.

FIG. 2 is a cross-sectional view of an embodiment of a substrate including a first copper carrier, a second copper carrier, and an insulating layer located therebetween.

FIG. 3 is a cross-sectional view of an embodiment of a first inner resist layer laminated on the first copper carrier and a second inner resist layer laminated on the second copper carriers of FIG. 2.

FIG. 4 is a cross-sectional view of an embodiment of a first seed layer formed on the first inner resist layer and a second seed layer formed on the second inner resist layer of FIG. 3.

FIG. 5 is a cross-sectional view of an embodiment of a first patterned dry film formed on the first seed layer and a second patterned dry film formed on the second seed layer of FIG. 4.

FIG. 6 is a cross-sectional view of an embodiment of a first inner plated layer formed on the exposed portion of the first seed layer, and a second inner plated layer formed on the exposed portion of the second seed layer of FIG. 5.

FIG. 7 is a cross-sectional view of an embodiment of a first and second wiring layer formed by removing the first patterned dry film, the first seed layer covered by the first patterned dry film, the second patterned dry film, and the second seed layer covered by the second patterned dry film of FIG. 6.

FIG. 8 is a cross-sectional view of an embodiment of a first build-up substrate, having a first dielectric layer and a first copper layer, laminated on the first inner wiring layer and a second build-up substrate, having a second dielectric layer and a second copper layer, laminated on the second inner wiring layer of FIG. 7.

FIG. 9 is a cross-sectional view of an embodiment of first blind holes defined in the first build-up substrate and second blind holes defined in the second build-up substrate of FIG. 8.

FIG. 10 is a cross-sectional view of an embodiment of first and second conductive vias formed by filling the first and second blind holes with plated copper, and first and second outer plated layers formed on the first and second build-up substrates of FIG. 9.

FIG. 11 is a cross-sectional view of an embodiment of a third patterned dry film formed on the first outer plated layer and a fourth patterned dry film formed on the second outer plated layer of FIG. 10.

FIG. 12 is a cross-sectional view of an embodiment of first and second outer wiring layers formed by removing the first outer plated layer, the first copper layer covered by the first outer plated layer, the second outer plated layer, and the second copper layer covered by the second outer plated layer of FIG. 11.

FIG. 13 is a cross-sectional view of an embodiment of a first and second outer resist layer formed on the first and second outer wiring layers of FIG. 12.

FIG. 14 is a cross-sectional view of the first copper carrier and the second copper carrier split from the insulating layer of FIG. 13.

FIG. 15 is a cross-sectional view of an embodiment of a part-embedded circuit structure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a method for manufacturing a part-embedded circuit structure. The method for manufacturing a part-embedded circuit structure comprising: forming an inner resist layer with an opening on a base member to expose a portion of the base member; forming an inner wiring layer on the inner resist layer which extends into the opening of the inner resist layer; laminating a dielectric layer on the inner wiring layer; forming an outer wiring layer on the dielectric layer opposite to the inner wiring layer; and removing the base member to expose the inner wiring layer in the opening and the inner resist layer such that a level plane is formed.

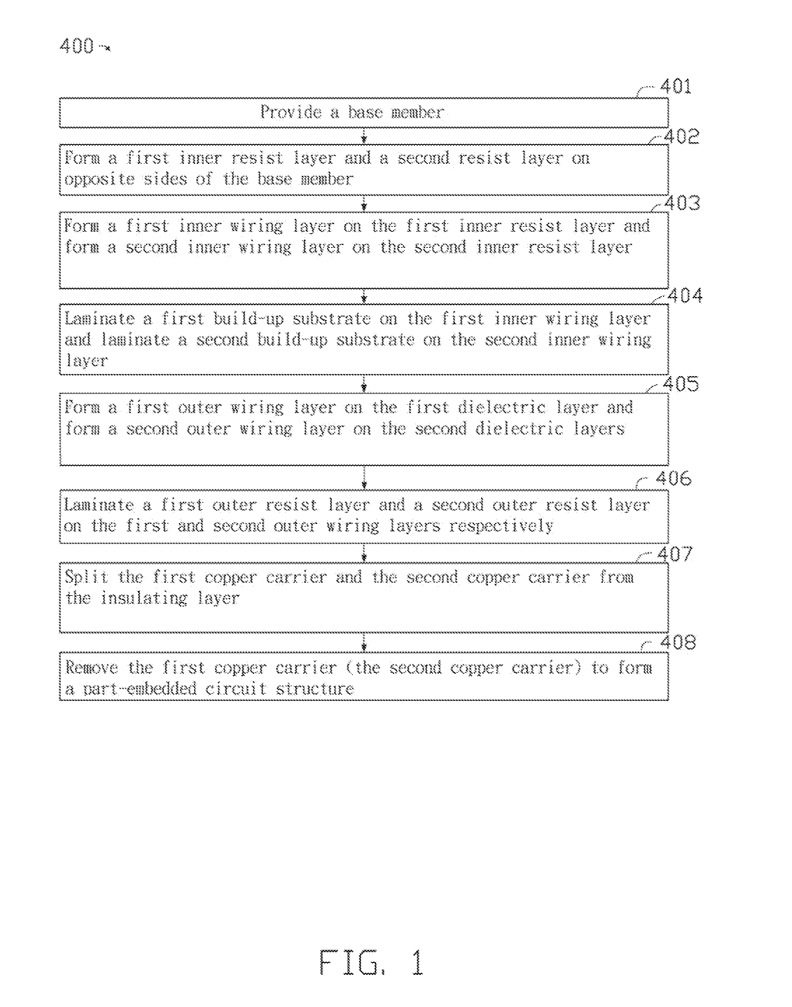

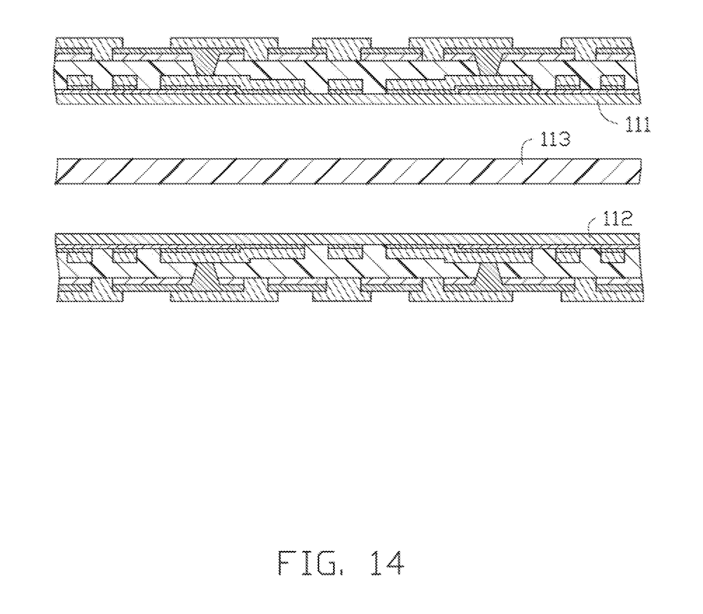

FIG. 1 illustrates a flowchart presented in accordance with an example embodiment. The example method 400 for manufacturing a part-embedded circuit structure (shown in FIG. 14) is provided by way of an example, as there are a variety of ways to carry out the method. Each block shown in FIG. 1 represents one or more processes, methods, or subroutines, carried out in the exemplary method 400. Additionally, the illustrated order of blocks is by example only and the order of the blocks can change. The exemplary method 400 can begin at block 401.

At block 401, a base member 100 is provided.

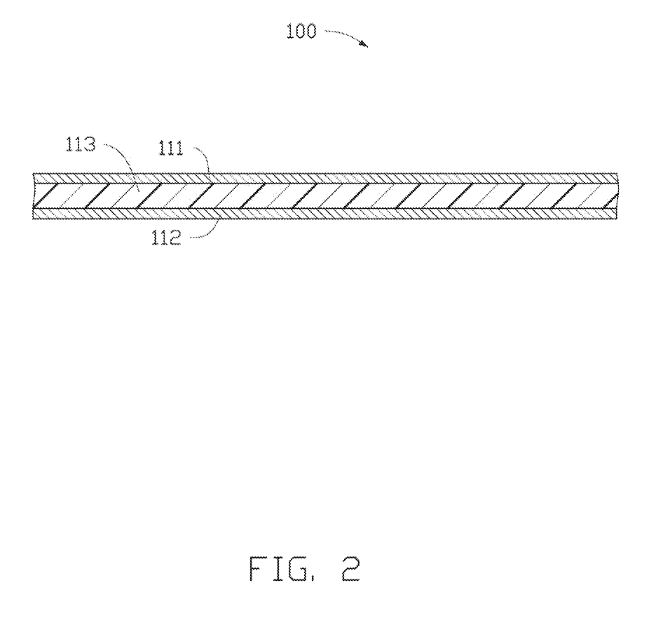

The base member 100 can be a single sided board or a double-sided board. In one embodiment, the base member 100 is a double-sided board. FIG. 2 illustrates that the base member 100 includes a first copper carrier 111, a second copper carrier 112, and an insulating layer 113. The first and second copper carriers 111 and 112 are located at opposite sides of the insulating layer 113. The first copper carrier 111, the insulating layer 113, and the second copper carrier 112 can be detachable.

At block 402, a first inner resist layer 121 and a second inner resist layer 122 are formed on opposite sides of the base member 100.

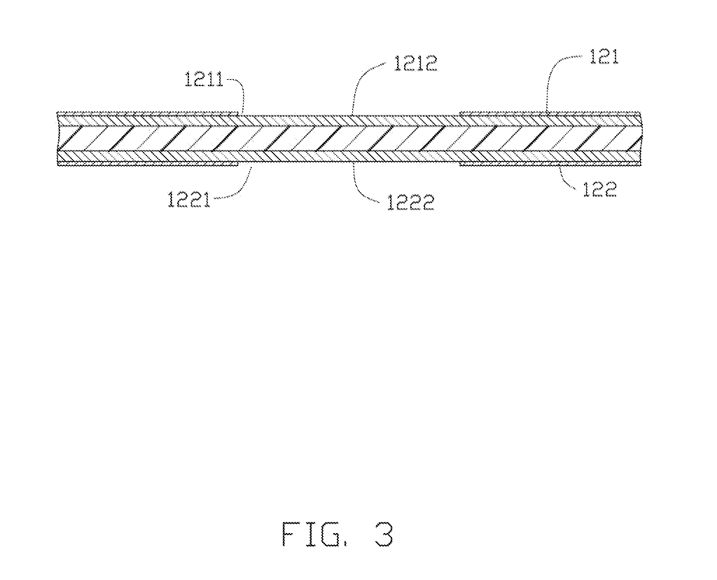

Referring to FIG. 3, the first inner resist layer 121 is laminated on the first copper carrier 111. The first inner resist layer 121 defines a first opening 1211. A portion of the base member 100 is exposed from the first opening 1211. In at least one embodiment, a portion of the first copper carrier 111 is exposed from the first opening 1211 to define a first exposed surface 1212. The second inner resist layer 122 is laminated on the second copper carrier 112. The second inner resist layer 122 defines a second opening 1221. A portion of the base member 100 is exposed from the second opening 1221. In at least one embodiment, a portion of the second copper carrier 112 is exposed from the second opening 1221 to define a second exposed surface 1222.

At block 403, a first inner wiring layer 161 is formed on the first inner resist layer 121 and a second inner wiring layer 162 is formed on the second inner resist layer 122.

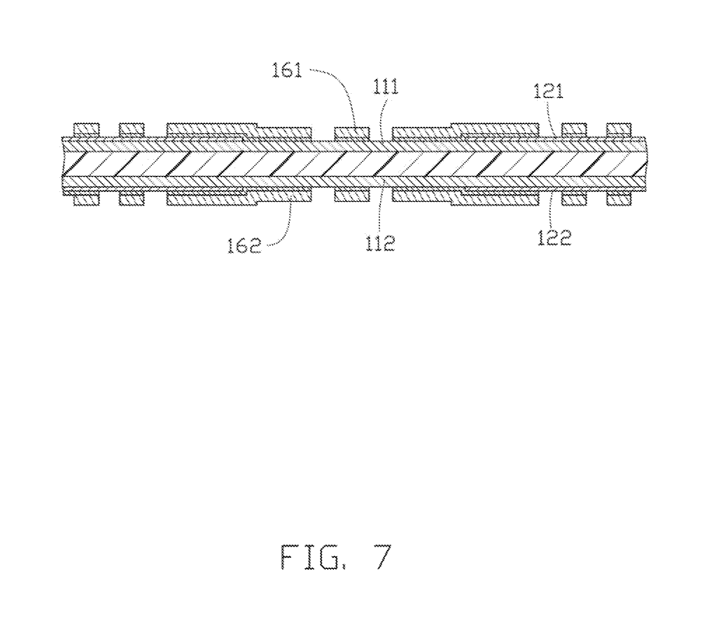

Referring to FIG. 7, the first inner wiring layer is formed on the first inner resist layer 121 and extends into the first opening 1211. The first inner wiring layer 161 defines an offset at the first opening 1211. That is, the first inner wiring layer 161 creeps from the first inner resist layer 121 into the first opening 1211 to define a height difference. A portion of the first inner resist layer 121 and a portion of the first copper carrier 111 are exposed from the first inner wiring layer 161. The second inner wiring layer 162 is formed on the second inner resist layer 122 and extends into the second opening 1221. The second inner wiring layer 162 defines an offset at the second opening 1221. That is, the second wiring layer 162 creeps from the second inner resist layer 122 into the second opening 1221 to define a height difference. A portion of the second inner resist layer 122 and a portion of the second copper carrier 112 are exposed from the second inner wiring layer 162.

In one embodiment, the first and second inner wiring layers 161 and 162 can be obtained in the following way.

A first seed layer 131 and a second seed layer 132 are formed on the first and second resist layers 121 and 122 respectively.

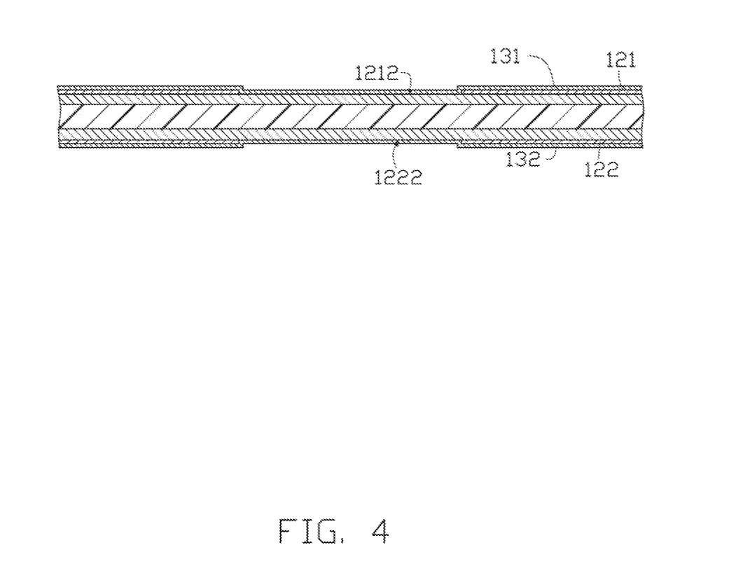

Referring to FIG. 4, the first seed layer 131 is formed on the first inner resist layer 121 and extends to the first exposed surface 1212. The first seed layer 131 on the first exposed surface 1212 and the first seed layer 131 on the first inner resist layer 121 define an offset or a height difference because of the first opening 1211. The second seed layer 132 is formed on the second inner resist layer 122 and extends to the second exposed surface 1222. The second seed layer 132 on the second exposed surface 1222 and the second seed layer 132 on the second inner resist layer 132 define an offset or a height difference because of the second opening 1221. The first and second seed layers 131 and 132 can be made of material selected from copper, aluminum, silver, and gold. The first and second seed layers 131 and 132 can be formed by chemical deposition.

A first patterned dry film 141 and a second patterned dry film 142 are formed on the first and second seed layers 131 and 132 respectively.

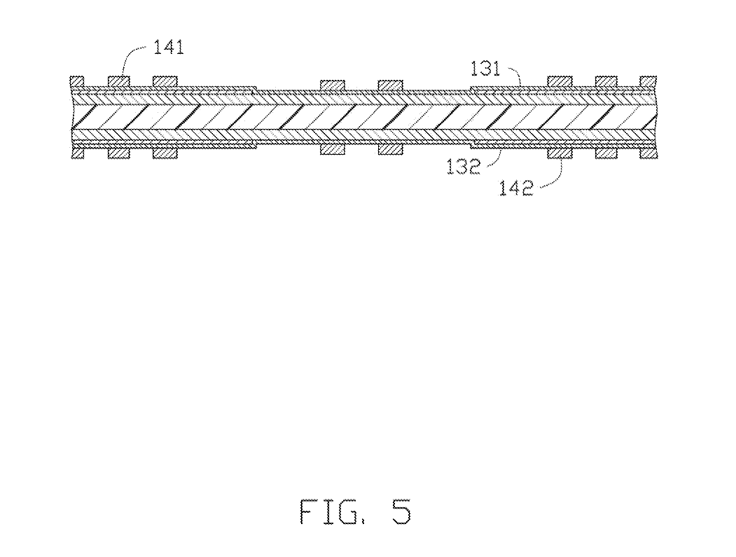

Referring to FIG. 5, the first patterned dry film 141 is formed on the first seed layer 131. A portion of the first seed layer 131 is exposed from the first patterned dry film 141. The second patterned dry film 142 is formed on the second seed layer 132. A portion of the second seed layer 132 is exposed from the second patterned dry film 142.

In one embodiment, the first patterned dry film 141 can be formed by means of laminating a first dry film on the first seed layer 131, to expose a portion of the first dry film substantially similar to the first patterned dry film 141, and then developing the other portion of the first dry film unexposed. The second patterned dry film 142 is formed by means of laminating a second dry film on the second seed layer 132, to expose a portion the second dry film substantially similar to the second patterned dry film 142, and then developing the other portion of the second dry film unexposed.

A first inner plated layer 151 and a second inner plated layer 152 are formed on the first and second seed layers 131 and 132 exposed from the first and second patterned dry films 141 and 142. The first and second inner plated layers 151 and 152 are made of conductive materials, such as copper, aluminum, silver, or gold. In at least one embodiment, the first and second inner plated layers 151 and 152 are made of copper.

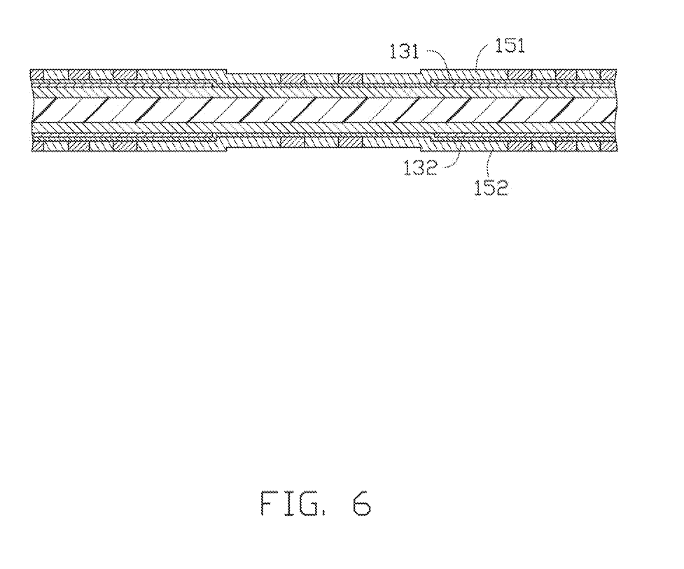

Referring to FIG. 6, the first inner plated layer 151 is formed on the first seed layer 131 exposed from the first patterned dry film 141. The second inner plated layer 152 is formed on the second seed layer 132 exposed from the second patterned dry film 142.

Referring to FIG. 7, the first and second patterned dry films 141 and 142, and the first and second seed layers 131 and 132 covered by the first and second patterned dry films 141 and 142 are removed to form the first and second inner wiring layers 161 and 162.

At block 404, a first build-up substrate 211 is laminated on the first inner wiring layer 161 and a second build-up substrate 212 is laminated on the second inner wiring layer 162.

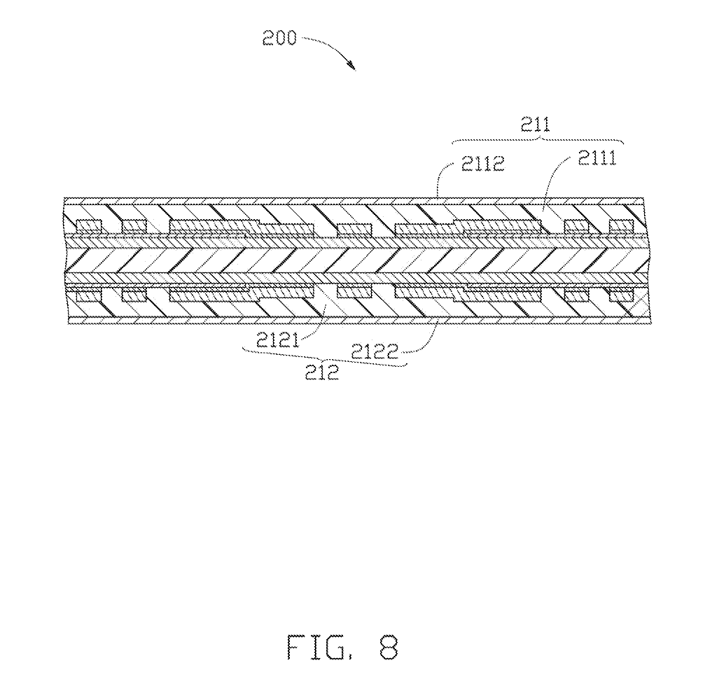

Referring to FIG. 8, the first build-up substrate 211 includes a first dielectric layer 2111 and a first copper layer 2112. The first dielectric layer 2111 is located between the first copper layer 2112 and the first inner wiring layer 161. The first dielectric layer 2111 covers the first inner wiring layer 161, the portion of the first inner resist layer 121 exposed from the first inner wiring layer 161, and the portion of the first copper carrier 111 exposed from the first inner wiring layer 161. The second build-up substrate 212 includes a second dielectric layer 2121 and a second copper layer 2122. The second dielectric layer 2121 is located between the second inner wiring layer 162 and the second copper layer 2122. The second dielectric layer 2121 covers the second inner wiring layer 162, the portion of the second inner resist layer 122 exposed from the second inner wiring layer 162, and the portion of the second copper carrier 112 exposed from the second inner wiring layer 162.

At block 405, a first outer wiring layer 241 is formed on the first dielectric layer 2111 and a second outer wiring layer 242 is formed on the second dielectric layers 2121.

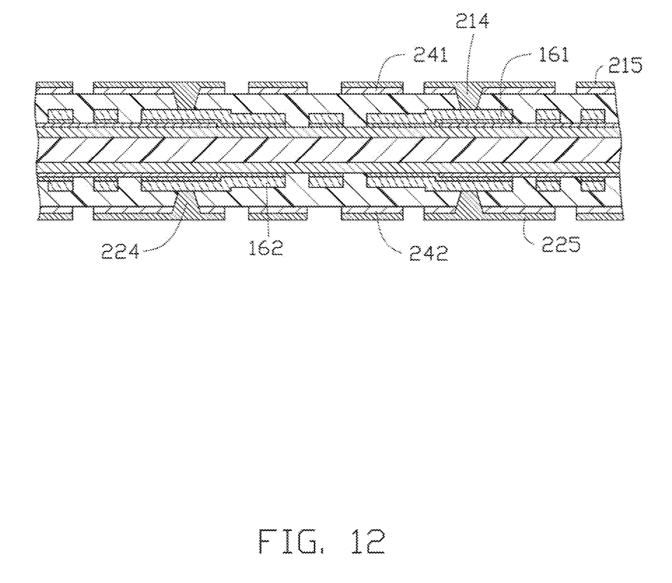

Referring to FIG. 12, the first outer wiring layer 241 is formed on the first dielectric layer 2111 opposite to the first inner wiring layer 161. The first outer wiring layer 241 and the first inner wiring layer 161 are electrically connected with each other via first conductive vias 214 defined in the first dielectric layer 2111. A portion of the first dielectric layer 2111 is exposed from the first outer wiring layer 241. The second outer wiring layer 242 is formed on the second dielectric layer 2121 opposite to the second inner wiring layer 162. The second outer wiring layer 242 and the second inner wiring layer 162 are electrically connected with each other via the second conductive vias 224 defined in the second dielectric layers 2121. A portion of the second dielectric layer 2121 is exposed from the second outer wiring layer 242.

In one embodiment, the first and second outer wiring layers 241 and 242 can be formed in following way.

A plurality of first conductive vias 214 and second conductive vias 224 are defined. In parallel with the formation of the first and second conductive vias 214 and 224, a first outer plated layer 215 and a second outer plated layer 225 are formed.

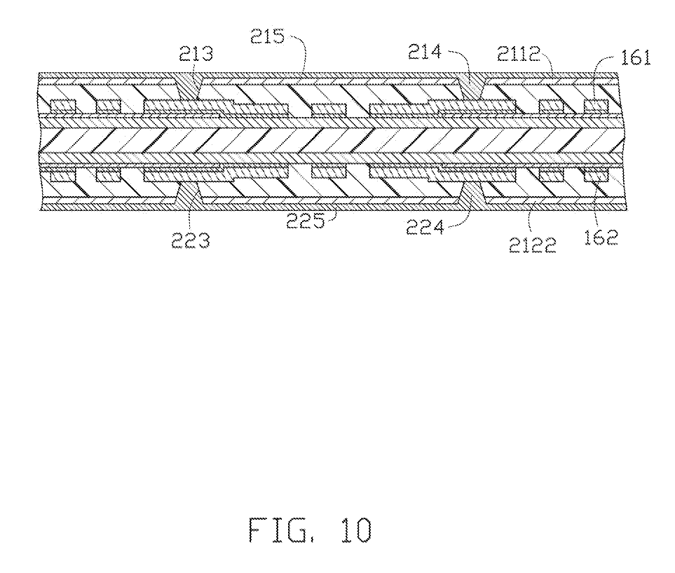

Referring to FIG. 10, the first conductive vias 214 run through the first dielectric layer 2111 and the first copper layer 2112. The second conductive vias 224 run through the second dielectric layer 2121 and the second copper layer 2122. The first outer plated layer 215 is formed on the first copper layer 2112 and electrically connects with the first conductive vias 214. The second outer plated layer 225 is formed on the second copper layer 2122 and electrically connects with the second conductive vias 224.

In one embodiment, the first conductive vias 214, the second conductive vias 224, the first outer plated layer 215, and the second outer plated layer 225 can be formed in following way.

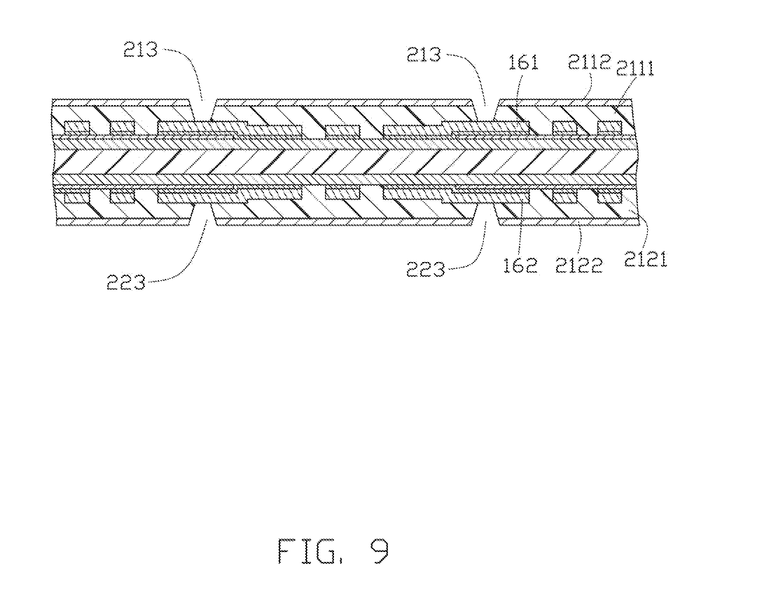

Referring to FIG. 9, a plurality of first blind holes 213 and a plurality of second blind holes 223 are defined. The first blind holes 213 run through the first dielectric layer 2111 and the first copper layer 2112, and reach the first inner wiring layer 161. A portion of the first inner wiring layer 161 is exposed from each first blind hole 213. The second blind holes 223 run through the second dielectric layer 2121 and the second copper layer 2122, and reach the second inner wiring layer 162. A portion of the second inner wiring layer 162 is exposed from each second blind hole 223.

Referring to FIG. 10, the first and second blind holes 213 and 223 are filled with plated copper to form the first and second conductive vias 214 and 224. In parallel with the formation of the the first and second conductive vias 214 and 224, the first outer plated layer 215 is formed on the first copper layer 2112, and the second outer plated layer 225 is formed on the second copper layer 2122.

A third patterned dry film 231 and a fourth patterned dry film 232 are formed on the first and second outer plated layers 215 and 225 respectively.

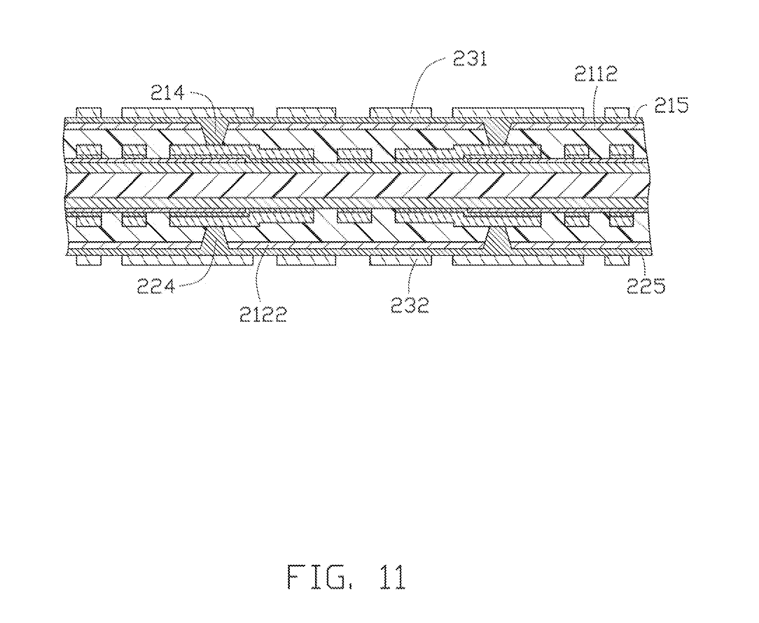

Referring to FIG. 11, the third patterned dry film 231 is formed on the first outer plated layer 215. The third patterned dry film 231 covers the first outer plated layer 215 and the first conductive vias 214. A portion of the first outer plated layer 215 is exposed from the third patterned dry film 231. The fourth patterned dry film 232 is formed on the second outer plated layer 225. The fourth patterned dry film 232 covers the second outer plated layer 225 and the second conductive vias 224. The method for forming the third patterned dry film 231 and the fourth patterned dry film 232 are similar to the method for forming the first and second patterned dry films 141 and 142 (see previous paragraph 0023).

The first outer plated layer 215 exposed from the third patterned dry film 231, the first copper layer 2112 covered by the first outer plated layer 215 exposed from the third patterned dry film 231, the second outer plated layer 225 exposed from the fourth patterned dry film 232, and the second copper layer 2122 covered by the second outer plated layer 225 exposed from the fourth patterned dry film 232 are removed. In one embodiment, the first outer plated layer 215 exposed from the third patterned dry film 231, the first copper layer 2112 covered by the first outer plated layer 215 exposed from the third patterned dry film 231, the second outer plated layer 225 exposed from the fourth patterned dry film 232, and the second copper layer 2122 covered by the second outer plated layer 225 exposed from the fourth patterned dry film 232 can be removed by etching.

The third and fourth patterned dry films 231 and 232 are removed to form the first and second outer wiring layers 241 and 242.

At block 406, a first outer resist layer 251 is laminated on the first outer wiring layer 241 and a second outer resist layer 252 is laminated on the second outer wiring layer 242.

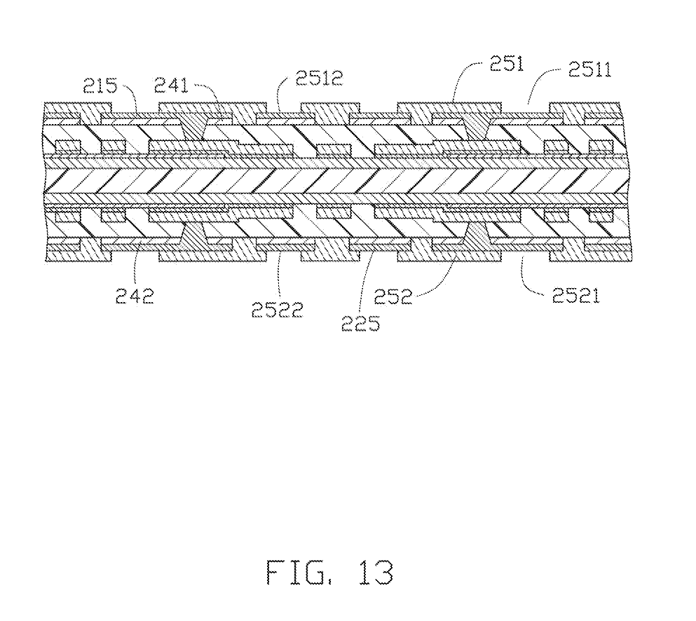

Referring to FIG. 13, the first outer resist layer 251 defines a plurality of third openings 2511. A portion of the first outer wiring layer 241 is exposed from each third opening 2511 to define a first pad 2512. The second outer resist layer 252 is formed on the second outer wiring layer 242. The second outer resist layer 252 defines a plurality of fourth openings 2521. A portion of the second outer wiring layer 242 is exposed from each fourth opening 2521 to define a second pad 2522.

At block 407, the first copper carrier 111 and the second copper carrier 112 are split from the insulating layer 113 as illustrated in FIG. 14.

At block 408, the first copper carrier 111 (the second copper carrier 112) is removed to form a part-embedded circuit structure 300.

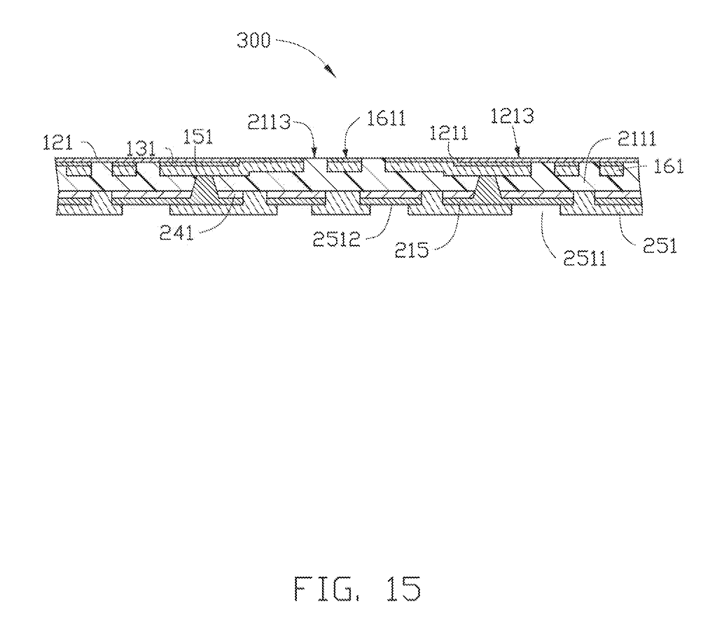

Referring to FIG. 15, the first copper carrier 111 is removed to expose the first inner resist layer 121, the first inner wiring layer 161 in the first opening 1211, and the first dielectric layer 2111 in the first opening 1211. Because of the offset at the first opening 1211, a surface of the part-embedded circuit structure 100 away from the first outer wiring layer 241 is substantially a plane. That is, a surface of the first inner resist layer 121 away from the first outer wiring layer 241, a surface of the exposed portion of the first inner wiring layer 161 away from the first outer wiring layer 241, and a surface of the exposed portion of first dielectric layer 2111 away from the first outer wiring layer 241 are locate in a same level plane.

In other embodiments, after forming the first and second outer resist layers 251 and 252 and before splitting the first and second copper carriers 111 and 112 from the insulating layer 113, the method for manufacturing the part-embedded circuit structure 300 may further include forming an anti-oxidation layer on each first and second pad 2512 and 2522.

In other embodiments, at block 401, the base member 100 is a single-sided board. The base member 100 includes a first copper carrier 111 and an insulating layer 113. The first copper carrier 111 is located at a side of the insulating layer 113. The first copper carrier 111 and the insulating layer 113 can be detachable. In this case, the method for manufacturing a part-embedded circuit structure 300 can include the treatment according to blocks 401 to 408 on a side of the first copper carrier 111.

Referring to FIG. 15, a part-embedded circuit structure 300, which can be manufactured via the method above, is illustrated.

The part-embedded circuit structure 300 includes a dielectric layer 2111, an inner wiring layer 161, an outer wiring layer 241, an inner resist layer 121, and an outer resist layer 121 and 251.

The inner wiring layer 161 is embedded in the dielectric layer 2111 and adjacent to one side of the dielectric layer 2111. The inner wiring layer 161 includes a seed layer 131 and a plated layer 151. The outer wiring layer 241 is located at another side of the dielectric layer 2111 opposite to the inner wiring layer 161. The outer wiring layer 241 is more adjacent to the plated layer 151 than the seed layer 131. The outer wiring layer 241 includes a copper layer 2112 an outer plated layer 215. The outer plated layer 215 faces away from the dielectric layer 2111. The inner resist layer 121 covers the inner wiring layer 161. The resist layer 121 defines an opening 1211. The inner wiring layer 161 extends into the opening 1211. A portion of the inner wiring layer 161 and a portion of the dielectric layer 2111 are exposed from the opening 1211. The inner wiring layer 161 defines an offset at the opening 1211. That is, the inner wiring layer 161 covered by the inner resist layer 121 creeps out from the opening 1211, to define a height difference, so that a surface of the part embedded circuit structure 100 away from the outer wiring layer 241 is substantially a plane. That is, a surface 1611 of the exposed portion of the inner wiring layer 161 away from the outer wiring layer 241, a surface 2113 of the exposed portion of dielectric layer 2111 away from the outer wiring layer 241, and a surface 1213 of the inner resist layer 121 away from the outer wiring layer 241 are located substantially in a same level plane. The outer resist layer 251 covers the outer wiring layer 241 defining a plurality of openings 2511. Each opening 2511 exposes a portion of the outer wiring layer 241 defining a pad 2512.

The embodiments shown and described above are only examples. Many details are often found in the art such as the other features of a part-embedded circuit structure and method for manufacturing the part-embedded circuit structure. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method for manufacturing a part-embedded circuit structure comprising:
forming an inner resist layer with an opening on a base member to expose a portion of the base member;
forming an inner wiring layer on the inner resist layer which extends into the opening of the inner resist layer;
laminating a dielectric layer on the inner wiring layer;
forming an outer wiring layer on the dielectric layer opposite to the inner wiring layer; and
removing the base member to expose the inner wiring layer in the opening and the inner resist layer such that a level plane is formed.

2. The method for manufacturing a part-embedded circuit structure of claim 1, wherein forming an inner wiring layer on the inner resist layer which extends into the opening of the inner resist layer comprises:
forming a seed layer on the inner resist layer which extends into the opening;
forming a patterned dry film on the seed layer;
forming an inner plated layer on the seed layer exposed from the patterned dry film; and
removing the patterned dry film and the seed layer covered by the patterned dry film.

3. The method for manufacturing a part-embedded circuit structure of claim 1, wherein a copper layer is laminated on the dielectric layer opposite to the inner wiring layer before laminating the dielectric layer on the inner wiring layer, and forming an outer wiring layer on the dielectric layer opposite to the inner wiring layer comprises:
defining a plurality of conductive vias in the dielectric layer and forming an outer plated layer on the copper layer;
forming a patterned dry film on the outer plated layer;
removing the outer plated layer exposed from the patterned dry film and the copper layer covered by the outer plated layer; and
removing the patterned dry film.

4. The method for manufacturing a part-embedded circuit structure of claim 3, wherein defining a plurality of conductive vias in the dielectric layer and forming an outer plated layer on the copper layer comprises:
defining a plurality of blind holes in the dielectric layer;
filling the blind holes with plated copper and forming an outer plated layer on the copper layer.

5. The method for manufacturing a part-embedded circuit structure of claim 1, after forming an outer wiring layer on the dielectric layer opposite to the inner wiring layer, and before removing the base member to expose the inner wiring layer in the opening and the inner resist layer, further comprising forming an outer resist layer on the outer wiring layer.

6. A part-embedded circuit structure comprising:
a dielectric layer;
an inner wiring layer part-embedded in the dielectric layer;
an outer wiring layer located at a side of the dielectric layer opposite to the inner wiring layer; and
an inner resist layer with an opening covering the inner wiring layer to expose a portion of the inner wiring layer and a portion of the dielectric layer;
wherein the inner wiring layer defines an offset at the opening, a surface of the part-embedded circuit structure away from the outer wiring layer is a level plane.

7. The part-embedded circuit structure of claim 6, further comprising a plurality of conductive vias, wherein the conductive vias run through the dielectric layer to electrically connect the inner wiring layer to the outer wiring layer.

8. The part-embedded circuit structure of claim 6, wherein the inner wiring layer includes a seed layer and an inner plated layer, the seed layer is exposed from the inner resist layer.

9. The part-embedded circuit structure of claim 8, further comprising an outer resist layer covering the outer wiring layer.

10. The part-embedded circuit structure of claim 9, wherein the outer resist layer covering the outer wiring layer defines a plurality of openings, a portion of the outer wiring layer is exposed from each opening defining a pad.
